(19) United States
(12) Patent Application Publication
(10) Pub. No.: US 2017/0016139 A1
(43) Pub. Date: Jan. 19, 2017

(54) Method for Producing Single Crystal of Polymer-Metal Complex

(71) Applicant: Takeda Pharmaceutical Company Limited, Osaka (JP)

(72) Inventor: Bunnai SAITO, Fujisawa (JP)

(21) Appl. No.: 15/252,626

(22) Filed: Aug. 31, 2016

(51) Int. Cl. C30B 7/14; C30B 29/58; C08F 292/00

(52) U.S. Cl. CPC C30B 7/14; C08F 292/00; C30B 29/58

(57) ABSTRACT

The present invention provides a method for producing a single crystal of a polymer-metal complex comprising:
(a) a step of dissolving in an organic solvent a tridentate ligand represented by formula (1):

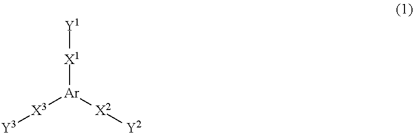

(wherein,
Ar represents an optionally substituted trivalent aromatic group,
X¹ to X³ each independently represent a divalent organic group, or a single bond that directly bonds Ar and Y¹, Y², or Y³, and
Y¹ to Y³ each independently represent a monovalent organic group having a coordinating moiety); and
(b) a step of obtaining the single crystal of the polymer-metal complex by adding to the solution obtained in step (a) a compound for providing the metal ion and an additive for changing solution properties to basic.

### TECHNICAL FIELD

The present invention relates to a method for producing a single crystal (crystal sponge) of a polymer-metal complex.

### BACKGROUND ART

As a method for determining a molecular structure of an organic compound, single crystal X-ray structural analysis is known. If a good-quality single crystal can be prepared, single crystal X-ray structural analysis is a very useful method because it enables the molecular structure of the organic compound to be precisely determined.

When the amount of the organic compound is small, it is difficult to prepare a good-quality single crystal. In such a case, using a single crystal of a polymer-metal complex is a useful way to prepare an X-ray crystallography sample. The term “single crystal of a polymer-metal complex” is also referred to as “crystal sponge”. A method for producing such a single crystal of a polymer-metal complex (a single crystal including an organic solvent is also embraced), and a method for preparing an X-ray crystallography sample by using a single crystal of a polymer-metal complex, are already known (refer to Patent Literature 1 to 4 and Non-Patent Literature 1 and 2).

### CITATION LIST

### Patent Literature

[Patent Literature 1] WO2014/038220A
[Patent Literature 2] WO2014/038221A
[Patent Literature 3] JP2006-188560A
[Patent Literature 4] JP2010-180307A
[Patent Literature 5] JP2008-214584A

### Non-Patent Literature

[Non-Patent Literature 1] Inokuma et al., Preparation and guest-uptake protocol for a porous complex useful for ‘crystal-free’ crystallography, Nature Protocols (2014), Vol. 9(2), pp. 246-252
[Non-Patent Literature 2] Inokuma et al., X-ray analysis on the nanogram to microgram scale using porous complexes, Nature (2013), Vol. 495, pp. 461-466

### SUMMARY OF INVENTION

### Technical Problem

There is a need for a more efficient method for producing a single crystal of a polymer-metal complex. To that end, it is an object of the present invention to provide a more efficient method for producing a single crystal of a polymer-metal complex.

### Solution to Problem

In view of the above-mentioned problem, the inventor searched for a method for increasing the efficiency of producing a single crystal of a polymer-metal complex, and discovered that production efficiency may be substantially increased by focusing on the acid-base chemical property of a solution, which until now had not been focused on in the production of a single crystal of a polymer-metal complex. As a result of further extensive studies, the inventor completed the present invention.

Specifically, the present invention relates to at least the following aspects.

[1] A method for producing a single crystal of a polymer-metal complex containing a tridentate ligand and a metal ion that serves as a center metal, the polymer-metal complex having a three-dimensional network structure in which the ligand is coordinated to the metal ion, and having pores and voids that are three-dimensionally arranged in the three-dimensional network structure in an ordered manner, the method comprising:

(a) a step of dissolving in an organic solvent a tridentate ligand represented by formula (1)

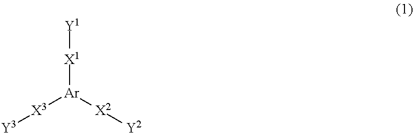

(wherein,

Ar represents an optionally substituted trivalent aromatic group,

X¹ to X³ each independently represent a divalent organic group, or a single bond that directly bonds Ar and Y¹, Y², or Y³, and

Y¹ to Y³ each independently represent a monovalent organic group having a coordinating moiety); and

(b) a step of obtaining a single crystal of the polymer-metal complex by adding to the solution obtained in step (a) a compound for providing the metal ion and an additive for changing solution properties to basic.

[2] The method for producing a single crystal of a polymer-metal complex according to [1], wherein the additive for changing solution properties to basic is a base selected from a hydroxide of an alkali metal, a hydroxide of an alkaline earth metal, an organic base, and an organometallic compound.
[3] The method for producing a single crystal of a polymer-metal complex according to [1], wherein the additive for changing solution properties to basic is lithium hydroxide, sodium hydroxide, potassium hydroxide, rubidium hydroxide, strontium hydroxide, 1,8-diazabicyclo[5.4.0]undec-7-ene, sodium bis(trimethylsilyl)amide, 1,1,3,3-tetramethylguanidine, or N,N-diisopropylethylamine.
[4] The method for producing a single crystal of a polymer-metal complex according to [1], wherein the metal ion that serves as a center metal is a cobalt ion or a zinc ion.
[5] The method for producing a single crystal of a polymer-metal complex according to [1], wherein the polymer-metal complex is represented by formula:

[(M(Z)₂)₃(L)₂]ₙ

(wherein,

M represents a metal ion,

Z represents a monovalent anion,

n represents an arbitrary natural number, and

L is a compound represented by formula (1)).

[6] A method for preparing a crystal structure analysis sample in which a molecule of an organic compound for which a molecular structure is to be determined is arranged in pores and voids of a polymer-metal complex crystal in an ordered manner, the method comprising:

(c) a step of bringing a polymer-metal complex crystal obtained by the production method according to [1] into contact with a first organic solvent; and

(d) a step of immersing the polymer-metal complex crystal of step (c) in a second organic solvent containing the organic compound for which a molecular structure is to be determined, and then concentrating by volatilizing the organic solvent under mild conditions.

[7] The method for preparing a crystal structure analysis sample according to [6], wherein the first organic solvent is an alkane solvent or a cycloalkane solvent.
[8] A kit for preparing a crystal structure analysis sample in which a molecule of an organic compound for which a molecular structure is to be determined is arranged in pores and voids of a polymer-metal complex crystal in an ordered manner, the kit comprising:

(i) a tridentate ligand represented by formula (1):

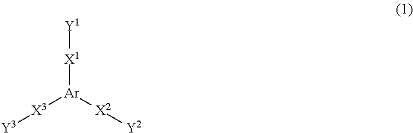

(wherein,

Ar represents an optionally substituted trivalent aromatic group,

X¹ to X³ each independently represent a divalent organic group, or a single bond that directly bonds Ar and Y¹, Y², or Y³, and

Y¹ to Y³ each independently represent a monovalent organic group having a coordinating moiety);

(ii) a compound for providing the metal ion that serves as a center metal of the polymer-metal complex; and

(iii) an additive for changing solution properties to basic.

### Effect Achieved by the Invention

According to one aspect of the invention, a more efficient method for producing a single crystal of a polymer-metal complex is provided. Specifically, according to one aspect of the invention, a larger number of single crystals of a polymer-metal complex may be rapidly formed.

Further, according to one aspect of the invention, the number of single crystals of a polymer-metal complex formed having a suitable size for X-ray crystallography may be increased.

Still further, according to one aspect of the invention, there is an advantage in that a single crystal of a polymer-metal complex may be easily recovered after being formed.

### BRIEF DESCRIPTION OF THE DRAWINGS

FIG. 1A is a photograph showing crystal sponges in a test tube in Step 5) of Example 1 confirmed using a stereomicroscope (OLYMPUS SZX16). As the additive for changing the solution properties to basic, rubidium hydroxide was used (same in FIG. 1B and FIG. 1C).

FIG. 1B is a photograph showing crystal sponges in nitrobenzene in Step 7) of Example 1 confirmed using a stereomicroscope (OLYMPUS SZX16).

FIG. 1C is a photograph showing crystal sponges in hexane (n-hexane) in Step 15) of Example 1 confirmed using a stereomicroscope (OLYMPUS SZX16).

FIG. 1D shows a network structure of the hexane-including polymer complex obtained in Example 1.

FIG. 1E shows the hexane-including polymer complex obtained in Example 1.

FIG. 1F is an enlarged view of the hexane-including polymer complex obtained in Example 1.

FIG. 2A is a photograph showing crystal sponges in a test tube in Step 5) of Example 9 confirmed using a stereomicroscope (OLYMPUS SZX16). As the additive for changing the solution properties to basic, 1,8-Diazabicyclo[5.4.0]undec-7-ene (DBU) was used (same in FIG. 2B and FIG. 2C).

FIG. 2B is a photograph showing crystal sponges in nitrobenzene in Step 7) of Example 9 confirmed using a stereomicroscope (OLYMPUS SZX16).

FIG. 2C is a photograph showing crystal sponges in hexane (n-hexane) in Step 15) of Example 9 confirmed using a stereomicroscope (OLYMPUS SZX16).

FIG. 3A is a photograph showing crystal sponges in a test tube in Step 5) of Example 11 confirmed using a stereomicroscope (OLYMPUS SZX16). As the additive for changing the solution properties to basic, 1,1,3,3-tetramethylguanidine (TMG) was used (same in FIG. 3B and FIG. 3C).

FIG. 3B is a photograph showing crystal sponges in nitrobenzene in Step 7) of Example 11 confirmed using a stereomicroscope (OLYMPUS SZX16).

FIG. 3C is a photograph showing crystal sponges in hexane (n-hexane) in Step 15) of Example 11 confirmed using a stereomicroscope (OLYMPUS SZX16).

FIG. 4A is a photograph showing crystal sponges in a test tube in Step 5) of Example 12 confirmed using a stereomicroscope (OLYMPUS SZX16). As the additive for changing the solution properties to basic, N,N′-diisopropylethylamine (DIPEA) was used (same in FIG. 4B and FIG. 4C).

FIG. 4B is a photograph showing crystal sponges in nitrobenzene in Step 7) of Example 12 confirmed using a stereomicroscope (OLYMPUS SZX16).

FIG. 4C is a photograph showing crystal sponges in hexane (n-hexane) in Step 15) of Example 12 confirmed using a stereomicroscope (OLYMPUS SZX16).

FIG. 5A is a photograph showing crystal sponges in a test tube in Step 5) of Example 13 confirmed using a stereomicroscope (OLYMPUS SZX16). As the additive for changing the solution properties to basic, bis(isopropyl)amine was used (same in FIG. 5B and FIG. 5C).

FIG. 5B is a photograph showing crystal sponges in nitrobenzene in Step 7) of Example 13 confirmed using a stereomicroscope (OLYMPUS SZX16).

FIG. 5C is a photograph showing crystal sponges in hexane (n-hexane) in Step 15) of Example 13 confirmed using a stereomicroscope (OLYMPUS SZX16).

FIG. 6A is a photograph showing crystal sponges in a test tube in Step 5) of Comparative Example 1 confirmed using a stereomicroscope (OLYMPUS SZX16).

FIG. 6B is a photograph showing crystal sponges in hexane (n-hexane) in Step 15) of Comparative Example 1 confirmed using a stereomicroscope (OLYMPUS SZX16).

### DESCRIPTION OF EMBODIMENTS

### Production Method of the Single Crystal of the Polymer-Metal Complex

One of the present inventions is, as described above, a method for producing a single crystal of a polymer-metal complex containing a tridentate ligand and a metal ion that serves as a center metal, the polymer-metal complex having a three-dimensional network structure in which the ligand is coordinated to the metal ion, and having pores and voids that are three-dimensionally arranged in the three-dimensional network structure in an ordered manner, the method comprising:

(a) a step of dissolving in an organic solvent a tridentate ligand represented by formula (1):

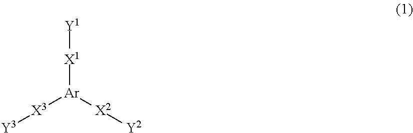

(wherein,

Ar represents an optionally substituted trivalent aromatic group,

X¹ to X³ each independently represent a divalent organic group, or a single bond that directly bonds Ar and Y¹, Y², or Y³, and

Y¹ to Y³ each independently represent a monovalent organic group having a coordinating moiety); and

(b) a step of obtaining a single crystal of the polymer-metal complex by adding to the solution obtained in step (a) a compound for providing the metal ion and an additive for changing solution properties to basic.

The three-dimensional network structure of the polymer-metal complex means a structure formed by the tridentate ligand that is coordinated to the metal ion, and has pores and voids (hereinbelow may be referred to as “the pores and the like”) that are three-dimensionally arranged in the three-dimensional network structure in an ordered manner.

“Pores and voids that are three-dimensionally arranged in the three-dimensional network structure in an ordered manner” means that the pores and voids that are arranged in the three-dimensional network structure in an ordered manner to such an extent that the pores and voids can be observed by X-ray single crystal structure analysis. “Pores formed in the three-dimensional network structure”, “pores of the polymer-metal complex”, and “pores formed in the single crystal” used in the present invention each have the same meaning. In addition, “void” in the present invention means an internal space of the spherical complex structure.

The tridentate ligand in the present invention is preferable if the unshared electron pairs (orbitals) of the three coordinating moieties are present in the same plane, and the three coordinating moieties are arranged radially with respect to the center of the tridentate ligand at an equal interval; “the three coordinating moieties are arranged radially with respect to the center of the tridentate ligand at an equal interval” means that the three coordinating moieties are arranged on lines that extend radially from the center of the ligand at an equal interval, at an almost equal distance from the center of the ligand.

Each step of the present inventive production method is further explained below.

[Step (a)]

Step (a) is a step of dissolving in an organic solvent a tridentate ligand represented by formula (1).

<Tridentate Ligand>

The number of carbon atoms of Ar is normally 3 to 22, preferably 3 to 13, and more preferably 3 to 6.

Examples of Ar include a trivalent aromatic group having a monocyclic structure that consists of one 6-membered aromatic ring, and a trivalent aromatic group having a fused ring structure in which three 6-membered aromatic rings are fused.

Examples of the trivalent aromatic group having a monocyclic structure that consists of one 6-membered aromatic ring include the groups respectively represented by the following formulas (2a) to (2d). Examples of the trivalent aromatic group having a fused ring structure in which three 6-membered aromatic rings are fused, include the group represented by the following formula (2e). Note that “*” in the formulas (2a) to (2e) indicates the positions at which X¹ to X³ are bonded.

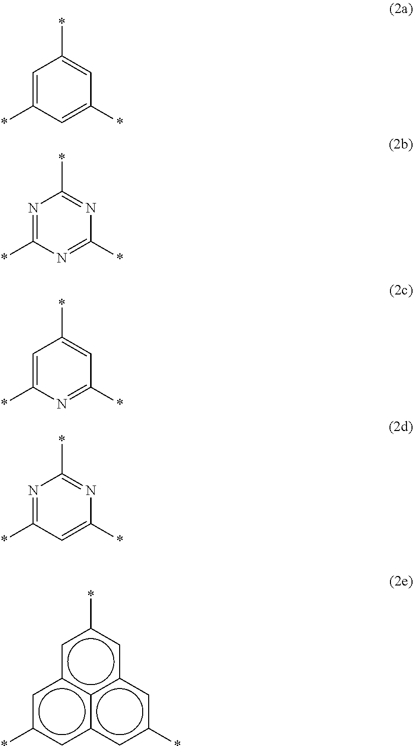

The aromatic groups represented by the formulas (2a) and (2c) to (2e) may be substituted with a substituent at an arbitrary position. Examples of a substituent include an alkyl group such as a methyl group, an ethyl group, an isopropyl group, an n-propyl group, and a t-butyl group; an alkoxy group such as a methoxy group, an ethoxy group, an n-propoxy group, and an n-butoxy group; a halogen atom such as a fluorine atom, a chlorine atom, and a bromine atom; and the like.

Ar is preferably the aromatic group represented by the formula (2a) or (2b), and particularly preferably the aromatic group represented by the formula (2b).

X¹ to X³ are independently a divalent organic group, or a single bond that directly bonds Ar and Y¹, Y², or Y³.

The divalent organic group that may be represented by X¹ to X³ is preferably a group that can form a pi electron conjugated system together with Ar. When the divalent organic group that may be represented by X¹ to X³ forms a pi electron conjugated system, the planarity of the tridentate ligand represented by the formula (1) is improved, and a strong three-dimensional network structure is easily formed.

The number of carbon atoms of the divalent organic group is preferably 2 to 18, more preferably 2 to 12, and still more preferably 2 to 6.

Examples of the divalent organic group include a divalent unsaturated aliphatic group having 2 to 10 carbon atoms, a divalent organic group having a monocyclic structure that consists of one 6-membered aromatic ring, a divalent organic group having a fused ring structure in which two to four 6-membered aromatic rings are fused, an amide group (—C(═O)—NH—), an ester group (—C(═O)—O—), a combination of two or more divalent organic groups among these divalent organic groups, and the like.

Examples of the divalent unsaturated aliphatic group having 2 to 10 carbon atoms include a vinylene group, an acetylene group (ethynylene group), and the like.

Examples of the divalent organic group having a monocyclic structure that consists of one 6-membered aromatic ring, include a 1,4-phenylene group and the like.

Examples of the divalent organic group having a fused ring structure in which two to four 6-membered aromatic rings are fused, include a 1,4-naphthylene group, a 1,5-naphthylene group, a 2,6-naphthylene group, an anthracene-1,4-diyl group, and the like.

Examples of a combination of two or more divalent organic groups among these divalent organic groups include the groups respectively represented by the following formulas.

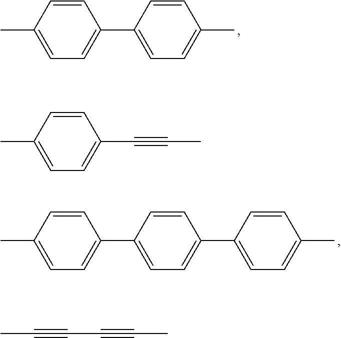

These aromatic rings may include a hetero atom such as a nitrogen atom, an oxygen atom, or a sulfur atom in their ring.

The divalent organic group may be substituted with a substituent. Examples of the substituent include those mentioned above in connection with Ar.

The groups respectively represented by the following formulas are preferable as the divalent organic group that may be represented by X¹ to X³.

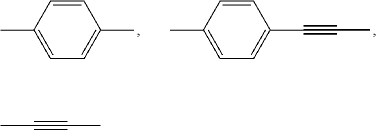

Y¹ to Y³ are independently a monovalent organic group having a coordinating moiety.

The organic group represented by Y¹ to Y³ is preferably a group that can form a pi electron conjugated system together with Ar and X¹ to X³.

When the organic group represented by Y¹ to Y³ forms a pi electron conjugated system, the planarity of the tridentate ligand represented by the formula (1) is improved, and a strong three-dimensional network structure is easily formed.

The number of carbon atoms of the organic group represented by Y¹ to Y³ is preferably 5 to 11, and more preferably 5 to 7.

Examples of the organic group represented by Y¹ to Y³ include the organic groups respectively represented by the following formulas (3a) to (3f). Note that “*” in the formulas (3a) to (3f) indicates the position at which X¹, X² or X³ is bonded.

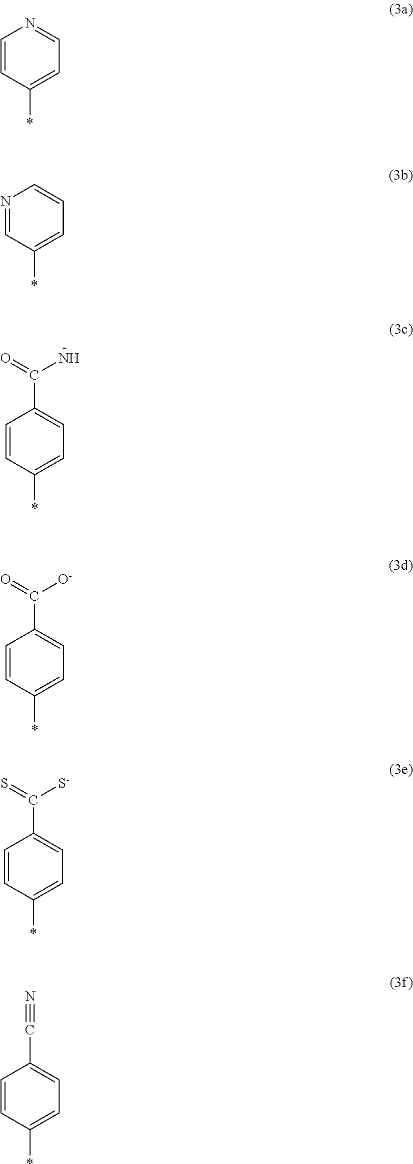 [SMILES: *c1ccncc1 ; *c1cccnc1 ; *c1ccc(C(N)=O)cc1 ; *c1ccc(C(=O)[O-])cc1 ; *c1ccc(C(=S)[S-])cc1 ; *c1ccc(C#N)cc1]

The organic groups represented by the formulas (3a) to (3f) may be substituted with a substituent at an arbitrary position. Examples of the substituent include those mentioned above in connection with Ar.

The group represented by the formula (3a) is particularly preferable as Y¹ to Y³.

The size of the pores and the like of the polymer-metal complex can be adjusted by appropriately selecting Ar, X¹ to X³, and Y¹ to Y³ in the tridentate ligand represented by the formula (1).

It is preferable that the tridentate ligand represented by the formula (1) have high planarity and high symmetry, and have a structure in which a pi-conjugated system extends over the entire ligand, since a strong three-dimensional network structure is easily formed. Examples of such a tridentate ligand include the ligands respectively represented by the following formulas.

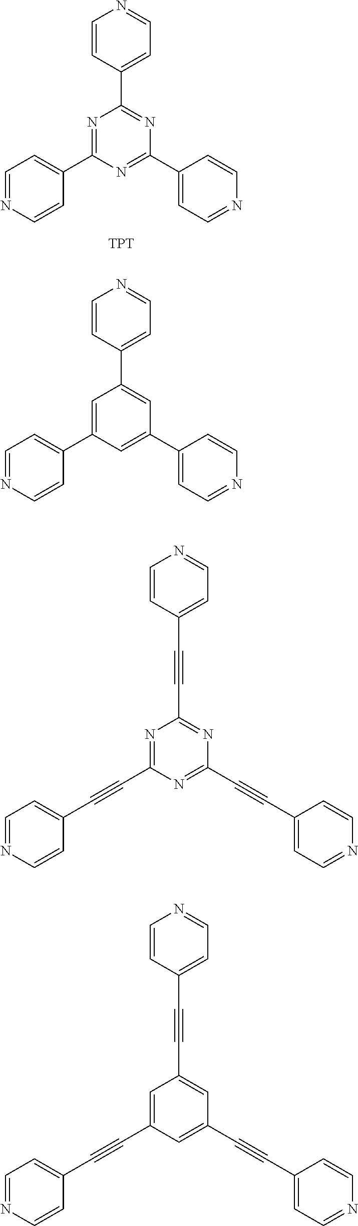

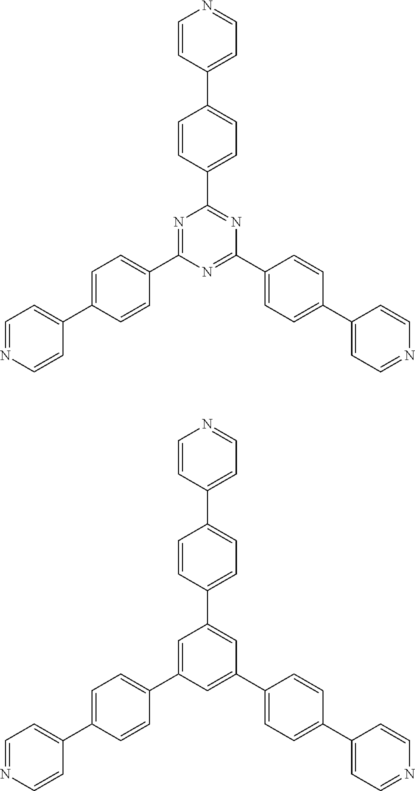 [SMILES: c1cc(-c2ccc(-c3nc(-c4ccc(-c5ccncc5)cc4)nc(-c4ccc(-c5ccncc5)cc4)n3)cc2)ccn1 ; c1cc(-c2ccc(-c3cc(-c4ccc(-c5ccncc5)cc4)cc(-c4ccc(-c5ccncc5)cc4)c3)cc2)ccn1]

Among these, 2,4,6-tris(4-pyridyl)-1,3,5-triazine (TPT) is particularly preferable as the tridentate ligand represented by the formula (1).

<Organic Solvent>

The organic solvent for dissolving the tridentate ligand also has a function for maintaining the cavities of the single crystal structure of the polymer-metal complex. The size of the cavities (pores) of the polymer-metal complex obtained by the production method according to one embodiment of the invention is from about 2 Å to about 30 Å when represented as an approximation of the diameter of an inscribed circle.

It is necessary for at least one kind of organic solvent used in step (a) to be replaced by another organic solvent, such as cyclohexane, in the step (step (c)) after inclusion in the polymer-metal complex. Therefore, as the organic solvent to be replaced, an organic solvent capable of being replaced in that manner is selected. Examples of this organic solvent include:

an aromatic hydrocarbon such as benzene, toluene, xylene, chlorobenzene, 1,2-dichlorobenzene, and nitrobenzene;

an aliphatic hydrocarbon such as n-pentane, n-hexane, and n-heptane;

an alicyclic hydrocarbon such as cyclopentane, cyclohexane, and cycloheptane;

a nitrile such as acetonitrile and benzonitrile;

an amide such as N-methylpyrrolidone;

an ether such as diethyl ether, tetrahydrofuran, 1,2-dimethoxyethane, and 1,4-dioxane;

an alcohol such as methanol, ethanol, and isopropyl alcohol;

a ketone such as acetone, methyl ethyl ketone, and cyclohexanone;

a cellosolve such as ethylcellosolve;

a halogenated hydrocarbon such as dichloromethane, chloroform, carbon tetrachloride, and 1,2-dichloroethane;

an ester such as methyl acetate, ethyl acetate, ethyl lactate, and ethyl propionate;

and the like. These solvents may be used either alone or in combination of two or more kinds thereof.

It is preferred that an alcohol be contained as the organic solvent. More specifically, a mixture of an alcohol and one or two or more kinds of organic solvent other than an alcohol is preferred as the organic solvent. As such a mixture, nitrobenzene/methanol and chloroform/methanol are particularly preferred.

The conditions for dissolving the tridentate ligand in the organic solvent are not limited. The tridentate ligand may be dissolved in the organic solvent by mixing and stirring the tridentate ligand and the organic solvent by an arbitrary method at a temperature equal to or less than room temperature.

[Step (b)]

Step (b) is a step of obtaining a single crystal of the polymer-metal complex by adding to the solution obtained in step (a) the compound providing the metal ion and the additive for changing the solution properties to basic.

In order to obtain the single crystal of the polymer-metal complex in step (b), the compound providing the metal ion and the additive for changing the solution properties to basic may be brought into contact with the solution obtained in step (a).

### <Additive for Changing Solution Properties to Basic>

In the production method according to one embodiment of the invention, more efficient production of the single crystal of the polymer-metal complex is achieved by adding to the solution obtained in step (a) the additive for changing the solution properties to basic.

This additive is not limited, as long as it is an additive that changes the solution properties of the solution obtained in step (a) to basic. Examples of preferred additives include a base selected from among a hydroxide of an alkali metal, a hydroxide of an alkaline earth metal, an organic base, and an organometallic compound.

More preferred examples of the additive include:

a hydroxide of an alkali metal, such as lithium hydroxide, sodium hydroxide, potassium hydroxide, rubidium hydroxide, and cesium hydroxide;

a hydroxide of an alkaline earth metal, such as strontium hydroxide;

an organic base, such as 1,8-diazabicyclo[5.4.0]undec-7-ene, 1,1,3,3-tetramethylguanidine, N,N-diisopropylethylamine, sodium methoxide, bis(isopropyl)amine, and n-butylamine; and

an organometallic compound such as sodium bis(trimethylsilyl)amide.

Among these examples, even more preferred are compounds that provide a monovalent cation, and rubidium hydroxide and bis(isopropyl)amine are particularly preferred.

<Compound Providing Metal Ion>

The compound providing the metal ion used in the production method according to one embodiment of the invention is not particularly limited. Examples thereof may include a compound represented by the formula MXₙ, in which M represents a metal ion, X represents a counterion, and n represents the valence of M.

The metal ion is not particularly limited, as long as the metal ion forms a coordination bond together with the multidentate ligand to form the three-dimensional network structure. A known metal ion may be used as the metal ion. Among those, an ion of a metal belonging to Groups 8 to 12 of the periodic table, such as an iron ion, a cobalt ion, a nickel ion, a copper ion, a zinc ion, or a silver ion is preferred, and more preferred is a divalent ion of a metal belonging to Groups 8 to 12 of the periodic table. Of those, a zinc(II) ion or a cobalt(II) ion is particularly preferred, since a polymer-metal complex having large pores and the like can be easily obtained.

Specific examples of X include F⁻, Cl⁻, Br, I⁻, SCN⁻, NO₃⁻, ClO₄⁻, BF₄⁻, SbF₄⁻, PF₆⁻, AsF₆⁻, CH₃CO₂⁻, and the like.

Examples of a preferred compound for providing the metal ion include ZnI₂, ZnBr₂, ZnCl₂, CoI₂, CoBr₂, and CoCl₂, and ZnI₂ is particularly preferred.

The method for adding the compound providing the metal ion and the additive for changing the solution properties to basic to the solution obtained in step (a) by dissolving the tridentate ligand represented by the above formula (1) in an organic solvent is not limited as long as the object according to one embodiment of the invention can be achieved; it is preferred to use a method in which the compound providing the metal ion and the additive for changing the solution properties to basic are added as a mixture. Regardless of the method that is used, the other conditions for obtaining the single crystal of the polymer-metal complex are not limited. The single crystal of the polymer-metal complex may be obtained by loading the mixture of the compound providing the metal ion and the additive for changing the solution properties to basic on the solution obtained in step (a), and then allowing the resultant to stand at 0 to 70° C. for from several hours to several days, for example. The concentration of the compound providing the metal ion and the concentration of the additive for changing the solution properties to basic are not particularly limited.

The polymer-metal complex crystal obtained in step (b) has a three-dimensional structure, and has pores and the like that are three-dimensionally arranged in the three-dimensional network structure in an ordered manner. The solvent (hereinafter sometimes also referred to as a crystallization solvent) used in step (a) is included in the pores and the like.

The production method according to one embodiment of the invention, in which the polymer-metal complex is represented by the formula [(M(Z)₂)₃(L)₂]ₙ (where M represents a metal ion, Z represents a monovalent anion, n represents an arbitrary natural number, and L is a compound represented by formula (1)), is preferred.

In the above formula, it is preferred that M and Z respectively correspond to the preferred metal ion mentioned above and the preferred counterion mentioned above.

Note that even though the polymer-metal complex crystal obtained in step (b) includes the crystallization solvent, the crystallization solvent is omitted from the above formula [(M(Z)₂)₃(L)₂]ₙ. When the included crystallization solvent is also written in the formula, the polymer-metal complex crystal may be written in the form, for example, {[M(Z)₂]₃(L)₂].x(solv)}ₙ or [M(Z)₂]₃(L)₂(solv)ₐ]_{b}, (where solv represents the crystallization solvent and n, X, a, and b each represent an arbitrary natural number. X and a are decimals if the crystallization solvent molecule is shared by two or more polymer-metal complex molecule).

In the polymer-metal complex represented by the above formula, it is preferred that M be a Zn(II) ion or a cobalt(II) ion (in this specification, these are sometimes written as “zinc ion” and “cobalt ion”, respectively). It is preferred that Z be CL, Br⁻, or I⁻, and I is particularly preferred. Further, it is preferred that L be 2,4,6-tris(4-pyridyl)-1,3,5-triazine (TPT).

Among the polymer-metal complexes represented by the above formula, preferred are [(ZnCl₂)₃(TPT)₂]ₙ, [(ZnBr₂)₃(TPT)₂]ₙ, [(ZnI₂)₃(TPT)₂]ₙ, [(CoCl₂)₃(TPT)₂]ₙ, [(CoBr₂)₃(TPT)₂]ₙ, and [(CoI₂)₃(TPT)₂]ₙ, and [ZnI₂)₃(TPT)₂]ₙ is particularly preferred.

When [(ZnI₂)₃(TPT)]ₙ includes the crystallization solvent, such a polymer-metal complex including the crystallization solvent may be represented by {[(ZnI₂)₃(TPT)₂].x(solv)}ₙ (where solv, n, and X have the same meaning as defined for the above formula).

For example, when the crystallization solvent is nitrobenzene, the polymer-metal complex including the organic solvent may be represented by {[(ZnI₂)₃(TPT)₂].x(PhNO₂)}ₙ, and when the crystallization solvent is methanol, the polymer-metal complex including the organic solvent may be represented by {[(ZnI₂)₃(TPT)₂].x(MeOH)}ₙ (where n and X have the same meaning as defined for the above formula).

According to the method for producing the single crystal of the polymer-metal complex according to one embodiment of the invention, the single crystal can be formed more efficiently than in a known method. Further, according to the production method according to one embodiment of the invention, the number of single crystals that are formed having a size (e.g., size of about 0.05 mm×about 0.05 mm×about 0.05 mm) suitable for X-ray crystallography can be increased.

In the production method according to one embodiment of the invention, although the number of single crystals of the polymer-metal complex produced during one production run by using about 0.1 mmol of the tridentate ligand is not limited, it is preferred that this number be 100 or more, and more preferred is 120 or more.

The structural analysis of the single crystal of the polymer-metal complex obtained by the production method according to one embodiment of the invention may be carried out by elemental analysis, thermogravimetry-mass spectrometry (TG-MS), powder X-ray crystallography, and the like.

Preparation Method of Crystal Structure Analysis Sample

One embodiment of the invention relates to a method for preparing a sample for analyzing the crystal structure of a molecule. A method for preparing this crystal structure analysis sample is now described.

[Step (c)]

Step (c) is a step of bringing the polymer-metal complex crystal including the crystallization solvent that has been obtained by the above production method into contact with a first organic solvent. By carrying out this step, the crystallization solvent included in the pores of the polymer-metal complex crystal is replaced by the first organic solvent.

The first organic solvent is not particularly limited, as long as it is capable of replacing the crystallization solvent in the pores of the polymer-metal complex crystal. It is preferred that the first organic solvent be an organic solvent that does not hinder incorporation of the organic compound that ultimately is to be incorporated into the pores and the like and is to be subjected to crystal structure analysis. Further, it is preferred that the first organic solvent be at least one solvent selected from the group consisting of an aliphatic hydrocarbon, an alicyclic hydrocarbon, an ether, an ester, an aromatic hydrocarbon, a halogenated hydrocarbon, and a nitrile. Among those, it is preferred that the first organic solvent be at least one solvent selected from the group consisting of an aliphatic hydrocarbon, an alicyclic hydrocarbon, and an aromatic hydrocarbon, more preferred are an aliphatic hydrocarbon and an alicyclic hydrocarbon, and particularly preferred are an alkane and a cycloalkane.

Further, an aliphatic hydrocarbon having 5 to 10 carbon atoms, an alicyclic hydrocarbon having 3 to 20 carbon atoms, and an aromatic hydrocarbon having 6 to 10 carbon atoms are preferred, and an aliphatic hydrocarbon having 5 to 10 carbon atoms and an alicyclic hydrocarbon having 5 to 10 carbon atoms are more preferred. As an aliphatic hydrocarbon having 5 to 10 carbon atoms, n-pentane, n-hexane, and n-octane are even more preferred, and as alicyclic hydrocarbon having 5 to 10 carbon atoms, cyclopentane, cyclohexane, cycloheptane, and the like, are even more preferred. Still even more preferred are n-hexane and cyclohexane, and hexane (n-hexane) is particularly preferred.

The method for bringing the single crystals of the polymer-metal complex obtained in step (b) into contact with the first organic solvent is not limited. This method may be carried out by, for example, bringing the single crystals of the polymer-metal complex together with a small amount of the crystallization solvent into contact with the first organic solvent, or by bringing a single crystals of the polymer-metal complex that has been left to stand in a small amount of the crystallization solvent into contact with the first organic solvent in such a manner that the concentration of the crystallization solvent is 1% v/v or less.

As the method for bringing the single crystals of the polymer-metal complex obtained in step (b) into contact with the first organic solvent, it is preferred to use a method that includes method bringing the single crystals of the polymer-metal complex into contact with a mixed solution of the first organic solvent and the crystallization solvent. For example, it is preferred to use a method in which the contact with the mixed solution of the first organic solvent and the crystallization solvent is carried out three times or more by gradually increasing the concentration of the first organic solvent while decanting. In the case of using such a mixed solution, the initial concentration of the first organic solvent may be, for example, 20% v/v to 30% v/v based on the total mixed solution, and the level by which the concentration is increased may be in the range of 15% v/v to 30% v/v.

It is more preferred to use a method that includes carrying out decantation a plurality of times so that the amount of the first organic solvent is ultimately greater by a factor of 10 to 20 times.

When [(ZnI₂)₃(TPT)₂]ₙ includes the first organic solvent, the polymer-metal complex including that organic solvent is represented by {[(ZnI₂)₃(TPT)₂].x(solv)}ₙ (where solv, n, and X have the same meaning as defined for the above formula). For example, when the organic solvent is n-hexane, the polymer-metal complex including the organic solvent is represented by {[(ZnI₂)₃(TPT)₂].x(hexane)}ₙ, and when the organic solvent is cyclohexane, the polymer-metal complex including the organic solvent is represented by {[(ZnI₂)₃(TPT)₂].x(c-hexane)}ₙ (where n and X have the same meaning as defined for the above formula).

[Step (d)]

Step (d) is a step of immersing the single crystals of the polymer-metal complex obtained in step (c) in a second organic solvent containing the organic compound for which a molecular structure is to be determined, and then concentrating by volatilizing the organic solvent under mild conditions. By carrying out step (d), the crystal structure analysis sample is prepared.

<Organic Compound for which Molecular Structure is to be Determined>

The organic compound for which a molecular structure is to be determined (hereinafter sometimes referred to as “organic compound (α)” is not particularly limited, as long as it is small enough to enter the pores and the like of the single crystals of the polymer-metal complex.

When the organic compound (α) is a low-molecular-weight compound, the molecular weight of the organic compound (α) is normally about 20 to about 3,000, and preferably about 100 to about 500.

When the organic compound (α) is a chain-like polymer compound (e.g., polyethylene) having a repeating unit, the molecular weight of the organic compound (α) is normally about 10³ to about 10⁶, and preferably about 10⁴ to about 10⁵. The organic compound (α) may be either a solid or a liquid around room temperature (about 25° C.).

In the method for preparing the crystal structure analysis sample according to an embodiment of the invention, it is preferred that the size of the organic compound (α) be roughly determined in advance by nuclear magnetic resonance spectroscopy, mass spectrometry, elemental analysis, or the like, and the single crystals of the polymer-metal complex be appropriately selected based on that size.

The concentration of the organic compound (α) in the solvent solution is not particularly limited; from the perspective of efficiently preparing a high-quality sample of crystal structure analysis, normally, the concentration is about 0.001 μg/μL to about 50 μg/μL, preferably about 0.01 μg/μL to about 5 μg/μL, and more preferably about 0.1 μg/μL to about 1 μg/μL.

<Second Organic Solvent>

The solvent to be used in the preparation of the solvent solution, namely, the second organic solvent, is not particularly limited, as long as it does not dissolve the single crystals of the polymer-metal complex, dissolves the organic compound (α), and is capable of concentrating the solvent solution of the organic compound (α) by being volatilized from the solvent solution of the organic compound (α).

From such a perspective, it is preferred that the second organic solvent have a boiling point at normal pressure (1×10⁵ Pa) of 0 to 250° C., more preferably about 0° C. to about 185° C., and even more preferably about 30° C. to about 150° C.

Examples of the second organic solvent may include:

an aromatic hydrocarbon such as benzene, toluene, xylene, chlorobenzene, and 1,2-dichlorobenzene;

an aliphatic hydrocarbon such as n-pentane, n-hexane, and n-heptane;

an alicyclic hydrocarbon such as cyclopentane, cyclohexane, and cycloheptane;

an ether such as diethyl ether, tetrahydrofuran, 1,2-dimethoxyethane, and 1,4-dioxane;

a halogenated hydrocarbon such as dichloromethane, chloroform, carbon tetrachloride, and 1,2-dichloroethane;

an ester such as methyl acetate, ethyl acetate, ethyl lactate, and ethyl propionate;

and the like. These solvents may be used either alone or in combination of two or more kinds thereof.

Among these examples of the second organic solvent, an ether, a halogenated hydrocarbon, and an ester are preferred. As an ether, tetrahydrofuran and 1,2-dimethoxyethane are preferred. As a halogenated hydrocarbon, chloroform is preferred. As an ester, ethyl acetate is preferred. As the second organic solvent, the same organic solvent as the first organic solvent may be used.

In the method for preparing the crystal structure analysis sample according to one embodiment of the invention, the single crystal (including the first organic solvent) of the polymer-metal complex according to that one embodiment of the invention is immersed in a solution of the second organic solvent that contains the organic compound (α).

The number of single crystals of the polymer-metal complex to be immersed is not particularly limited. When the amount of the organic compound (α) is very small, the target crystal structure analysis sample can be obtained by immersing one single crystal. When there is a sufficient amount of the organic compound (α), two or more single crystals of an identical polymer-metal complex may be immersed, or single crystals of different polymer-metal complexes may be immersed at the same time.

In the method for preparing the crystal structure analysis sample according to one embodiment of the invention, the single crystal of the polymer-metal complex is immersed in the solvent solution, and the solvent solution is then concentrated by volatilizing the solvent under mild conditions. This process enables a trace amount of the organic compound (α) to be efficiently incorporated into the pores and the like of the single crystal of the polymer-metal complex.

The immersion conditions (concentration conditions) at this point are not particularly limited. The temperature of the solvent is preferably about 0° C. to about 180° C., more preferably about 0° C. to about 80° C., and still more preferably about 20° C. to about 60° C.

The immersion time (concentration time) is normally 6 hours or more, preferably about 12 to about 168 hours, and more preferably about 24 to about 78 hours.

The volatilization rate of the solvent is preferably about 0.1 μL/24 hours to about 1,000 μL/24 hours, more preferably about 1 μL/24 hours to about 100 μL/24 hours, and still more preferably about 5 μL/24 hours to about 50 μL/24 hours.

The temperature employed when volatilizing the solvent is determined by taking account of the boiling point of the organic solvent to be used, but is normally about 0° C. to about 180° C., preferably about 0° C. to about 120° C., and more preferably about 15° C. to about 60° C.

The operation for immersing the single crystal of the polymer-metal complex in the solvent solution of the organic compound (α) and then volatilizing the solvent to concentrate the solvent solution may be performed under normal pressure, or may be performed under reduced pressure, or may be performed under pressure.

The pressure employed during the operation for volatilizing the solvent to concentrate the solvent solution is normally about 1 Pa to about 1×10⁶ Pa, and preferably about 1×10 Pa to 1×10⁶ Pa.

Therefore, the volatilization rate of the solvent can be appropriately adjusted by adjusting the temperature and the pressure employed during the operation for concentrating the solvent solution.

It is preferred that the crystal structure analysis sample obtained by the method for preparing the crystal structure analysis sample according to one embodiment of the invention has an occupancy ratio of the molecules of the organic compound (α) of 10% or more. This occupancy ratio represents, when the amount of included guest molecules [organic compound (α)] in a theoretical inclusion state is taken to be 100%, the amount of guest molecules actually present in the single crystal of the polymer-metal complex. In the method according to one embodiment of the invention, the occupancy ratio is preferably about 15% or more, and more preferably about 20% or more.

According to another embodiment of the invention, a kit is provided for preparing a crystal structure analysis sample in which a molecule of an organic compound for which a molecular structure is to be determined is arranged in pores and voids of a single crystals of a polymer-metal complex crystal in an ordered manner. This kit comprises:

(i) a tridentate ligand represented by formula (1);

(ii) a compound for providing the metal ion that serves as a center metal of the polymer-metal complex; and

(iii) an additive for changing the solution properties to basic.

The tridentate ligand, the compound, and the additive mentioned above respectively correspond to the tridentate ligand, the compound, and the additive used in the method for producing a single crystal of a polymer-metal complex according to one embodiment of the invention.

### EXAMPLES

The invention is further described below by way of examples. Note that the invention is not limited to the following examples.

### Example 1

### Production Method of Crystal Sponges Using Rubidium Hydroxide

### (Formation of Crystal Sponges—Collection of the Crystals—Storage in Nitrobenzene)

With the following steps 1)-15) (wording of “step” has been omitted, only with numbers followed by closing parenthesis), crystal sponges ({[(ZnI₂)₃(TPT)₂].x(hexane)}ₙ) were obtained (n and X represent natural numbers specified by the formed crystals. If the hexane molecule is shared with two crystals, n is a decimal):

1) TPT (2,4,6-tri(pyridin-4-yl)-1,3,5-triazine)*¹ (0.312 g, 1.00 mmol) was dissolved in a mixture of nitrobenzene (200.0 ml, WAKO) and MeOH (50.0 ml, WAKO) at room temperature. *¹ The purity of TPT was confirmed by elemental analysis. (TCI or WAKO)
2) 49 test tubes*² (N-16, Maruemu) were prepared, and then 5 mL of the solution was added into each test tube. ^{*2} Test tubes are not necessarily brand-new ones.
3) In another flask, Zinc iodide*³ (0.638 g, 2.00 mmol) and Rubidium hydroxide solution*⁴ (0.059 ml, 0.50 mmol, 50 wt. % in H₂O) was dissolved in MeOH (50.0 ml, WAKO). ^{*3} ZnI₂ (purity: 99.99%) was purchased from KOJYUNDO CHEMICAL LABORATORY CO., LTD.^{*4} Rubidium hydroxide solution was purchased from Sigma-Aldrich.
4) Using a micropipette, 1 mL of ZnI₂/RbOH solution was layered onto the solution of ligand in each test tube.
5) The caps were screwed on the test tubes, and then the test tubes were placed at 26° C. for about 3 days (this period can be about 2-3 days to about 1 week) to obtain crystals.
6) The resulting crystals on the wall surface were dropped to the bottom of the test tubes by ultrasound whose exposure time was ca. one second. Crystals on the bottom in each tube were taken up with a small amount of the mother liquid using a pipette and combined into a test tube.
7) Nitrobenzene (ca. 10 mL) was added to the test tube and the mixture of 6) was gently shaken. The solvent was again reduced to ca. 1 mL by decantation, and then nitrobenzene (ca. 10 mL) was added to the test tube and the mixture was gently shaken again.
8) The solvent was reduced to ca. 5 mL and ca. 5 mL of 25% hexane (WAKO) in nitrobenzene was added and the mixture was gently shaken.
9) The solvent was reduced to ca. 5 mL and ca. 5 mL of 50% hexane in nitrobenzene was added and the mixture was gently shaken.
10) The solvent was reduced to ca. 5 mL and ca. 5 mL of 75% hexane in nitrobenzene was added and the mixture was gently shaken.
11) The solvent was reduced to ca. 5 mL and ca. 5 mL of 90% hexane in nitrobenzene was added and the mixture was gently shaken.
12) The solvent was reduced to ca. 1.0 mL and ca. 15 ml of hexane was added and the mixture was gently shaken.
13) The solvent was reduced to ca. 1.0 mL and ca. 15 ml of hexane was added and the mixture was gently shaken. The test tube was stored in an incubator at 50° C. for 3 days.
14) The solvent was reduced to ca. 1.0 mL and ca. 15 ml of hexane was added and the mixture was gently shaken. The test tube was stored in an incubator at 50° C. for 2 days.
15) The solvent was reduced to ca. 1.0 mL and ca. 15 ml of hexane was added. The test tube was stored at room temperature.

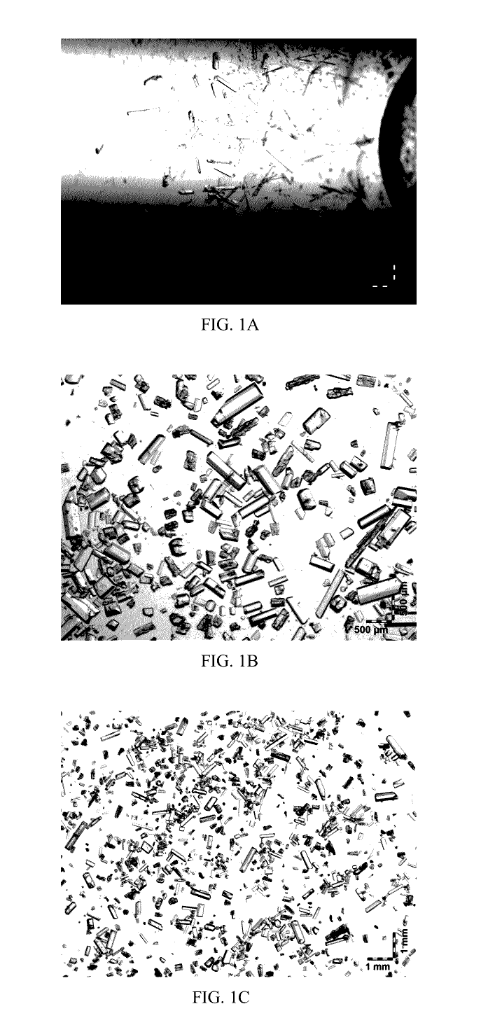

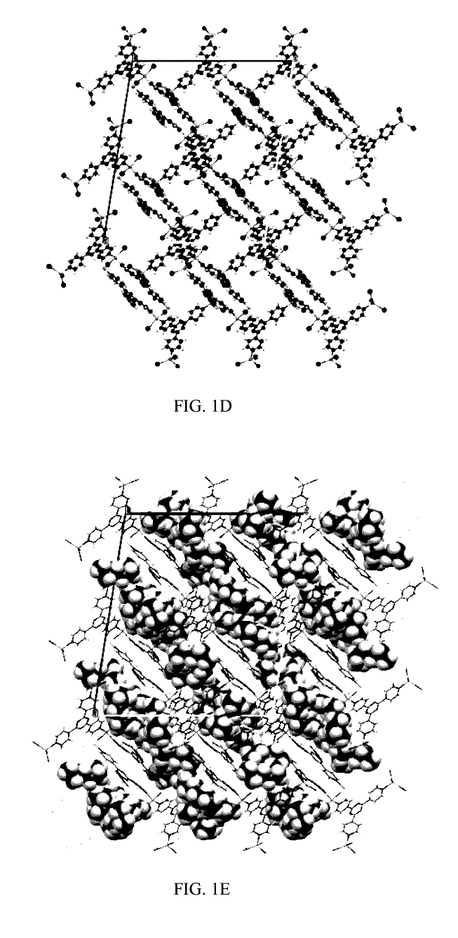

In the above Steps 5), 7), and 15), crystal sponges were confirmed using a stereomicroscope (OLYMPUS SZX16) (FIG. 1A to FIG. 1C).

Further, among the crystal sponges obtained in the manner described above, no cracks or blemishes could be seen under the microscope, and the number of crystal sponges having a size of about 0.05 mm×0.05 mm×0.05 mm was measured.

The average number of crystal sponges that were formed in three test tubes randomly selected from among 49 test tubes in which the above procedures had been simultaneously carried out was 165 (first test tube: 173 crystal sponges, second test tube: 209 crystal sponges, third test tube: 113 crystal sponges).

Single crystal X-ray structure analysis was conducted on the crystal sponges obtained in Example 1 with the method as described below:

A single crystal obtained by Example 1 was coated with oil base cryoprotectant (Parabar 10312, Hampton Research Corp.) and mounted on a MicroLoops™.

Diffraction data were collected at 93 K under a cold nitrogen gas stream on a Rigaku XtaLAB Pro MM007DW X-ray diffractometer system, using multi-layer mirror monochromated Mo-Kα radiation (λ=0.71075 Å). Intensity data were collected by an ω-scan with 0.5° oscillations for each frame. Bragg spots were integrated using the CrysAlisPro program package, and the empirical absorption correction (multi-scan) was applied using the SCALE3 ABSPACK program. Structures were solved by direct methods (SHELXT Version 2014/4) and refined by full-matrix least squares (SHELXL Version 2014/7). Anisotropic temperature factors were applied to all non-hydrogen atoms. Hydrogen atoms were placed at calculated positions and refined applying riding models.

The crystal data of the crystal sponges obtained in example 1 are shown in Table 1 below. Occupancy of hexane was 100%.

TABLE 1
Crystal data

| formula | C₆₀H₈₀I₆N₁₂Zn₃ | |
|---|---|---|
| FW | 1926.94 | |
| T/K | 93 | |
| wavelength/Å | 0.71075 | (Mo Kα) |
| color | colorless | |
| crystal size, mm | 0.324 × 0.120 × 0.080 | |
| crystal system | monoclinic | |
| space group | C2/c (#15) | |
| α/Å | 33.8320 | (14) |
| b/Å | 15.0571 | (4) |
| c/Å | 29.5332 | (12) |
| α/deg | 90.000 | |
| β/deg | 99.076 | (4) |
| γ/deg | 90.000 | |
| V/Å | 14856.2 | (10) |

| | |
|---|---|
| Z | 8 |
| Dₓ/g cm⁻³ | 1.723 |
| μ/mm⁻¹ | 3.498 |
| reflections collected | 63291 |
| unique reflections | 15615 |
| refined parameters | 868 |
| GOF on F² | 1.141 |
| R1 [I > 2σ(I)]^{a} | 0.1191 |
| wR2 (all data)^{b} | 0.3057 |
| Δρ_{min, max}/e Å⁻³ | 1.56, −1.29 |

^{a}R1 = Σ ||Fo| − |Fc||/Σ |Fo|,
^{b}wR2 = [Σ (w(Fo² − Fc²)²)/Σ w(Fo²)²]^{1/2}

Crystal structures of the crystal sponges obtained Example 1 are shown in FIGS. 1D, 1E and 1F. FIG. 1D shows a network structure of the hexane-including polymer complex (hexane-including polymer complex) obtained in Example 1. FIG. 1E shows the same hexane-including polymer complex obtained in Example 1; FIG. 1F is an enlarged view of the same hexane-including polymer complex.

### Example 2

### Production Method of Crystal Sponges Using Sodium Hydroxide

Crystal sponges were produced by the same method as in Example 1 using 125 μl (1.0 mmol) of aqueous sodium hydroxide (8 mol/L, WAKO) instead of the aqueous rubidium hydroxide of Step 3).

### Example 3

### Production Method of Crystal Sponges Using Sodium Methoxide

Based on the same method as in Example 1, in Steps 1) to 4), a solution obtained by dissolving TPT (156 mg, 0.50 mmol) in a nitrobenzene (100 ml)/MeOH (25 ml) mixture was dispensed into each of 24 test tubes, and in Step 3), 319 mg (1.00 mmol) of zinc iodide and sodium methoxide (14 mg, 0.25 mmol, WAKO) were dissolved in MeOH (25 ml).

In Steps 5), 7), and 15), crystal sponges were confirmed using a stereomicroscope (OLYMPUS SZX16) at about 40× magnification, and similar results to those of Example 1 were also confirmed.

### Example 4

### Production Method of Crystal Sponges Using Potassium Hydroxide

Based on the same method as in Example 1, in Steps 1) to 4), 24 test tubes were prepared, 5 ml of a solution obtained by dissolving 156 mg (0.50 mmol) of TPT in a nitrobenzene (100 ml)/MeOH (25 ml) mixture was dispensed into each test tube, and 1 ml of a solution obtained by dissolving 319 mg (1.00 mmol) of zinc iodide and 2.5 ml (0.1 mol/l in 0.5 mmol MeOH, Kanto Kagaku) of KOH in MeOH (22.5 ml) was further dispensed into each test tube.

In Steps 5), 7), and 15), crystal sponges were confirmed using a stereomicroscope (OLYMPUS SZX16) at about 40× magnification in the same manner as in Example 1.

### Example 5

### Production Method of Crystal Sponges Using Strontium Hydroxide

Based on the same method as in Example 1, in Steps 1) to 4), 24 test tubes were prepared, 5 ml of a solution obtained by dissolving 156 mg (0.50 mmol) of TPT in a nitrobenzene (100 ml)/MeOH (25 ml) mixture was dispensed into each test tube, and 1 ml of a solution obtained by dissolving 319 mg (1.00 mmol) of zinc iodide and 66 mg (0.25 mmol, WAKO) of strontium hydroxide octahydrate in MEOH (25 ml) was further dispensed into each test tube.

In Step 7), crystals were observed using a stereomicroscope, and the presence of crystal sponges was confirmed in the same manner as in Example 1.

### Example 6

### Production Method of Crystal Sponges Using Cesium Hydroxide

Based on the same method as in Example 1, in Steps 1) to 4), 24 test tubes were prepared, 5 ml of a solution obtained by dissolving 156 mg (0.50 mmol) of TPT in a nitrobenzene (100 ml)/MeOH (25 ml) mixture was dispensed into each test tube, and 1 ml of a solution obtained by dissolving 319 mg (1.00 mmol) of zinc iodide and 75 mg (0.25 mmol, Sigma Aldrich) of cesium hydroxide in MeOH (25 ml) was further dispensed into each test tube.

In Steps 5), 7), and 15), crystal sponges were confirmed using a stereomicroscope (OLYMPUS SZX16) at about 40× magnification in the same manner as in Example 1.

### Example 7

### Production Method of Crystal Sponges Using Nitrobenzene/Ethanol as TPT Solvent

Based on the same method as in Example 1, in Steps 1) to 4), 24 test tubes were prepared, 6 ml of a solution obtained by dissolving 156 mg (0.50 mmol) of TPT in a nitrobenzene (100 ml)/EtOH (50 ml, WAKO) mixture was dispensed into each test tube, and 1 ml of a solution obtained by dissolving 319 mg (1.00 mmol) of zinc iodide and 29 μl (50% w/w, 0.25 mmol) of rubidium hydroxide in EtOH (25 ml) was further dispensed into each test tube.

In Steps 5), 7), and 15), crystals were observed using a stereomicroscope, and the presence of crystal sponges was confirmed in the same manner as in Example 1.

### Example 8

### Production Method of Crystal Sponges Using Nitrobenzene/Isopropanol as TPT Solvent Solution

Based on the same method as in Example 1, in Steps 1) to 4), 24 test tubes were prepared, 6 ml of a solution obtained by dissolving 156 mg (0.50 mmol) of TPT in a nitrobenzene (100 ml)/isopropanol (50 ml, WAKO) mixture was dispensed into each test tube, and 1 ml of a solution obtained by dissolving 319 mg (1.00 mmol) of zinc iodide and 29 μl (50% w/w, 0.25 mmol) of rubidium hydroxide in isopropanol (25 ml) was further dispensed into each test tube.

In Steps 5), 7), and 15), crystal sponges were observed using a stereomicroscope, and the presence of crystal sponges was confirmed in the same manner as in Example 1.

### Example 9

### Production Method of Crystal Sponges Using 1,8-Diazabicyclo[5.4.0]undec-7-ene (DBU)

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol) of zinc iodide and 37 μl (0.25 mmol) of DBU in MeOH (25 ml) was added thereto.

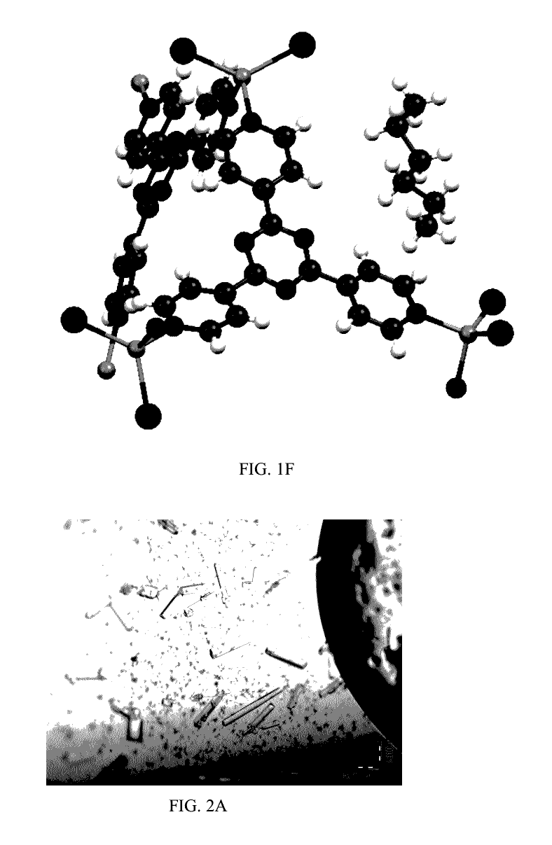

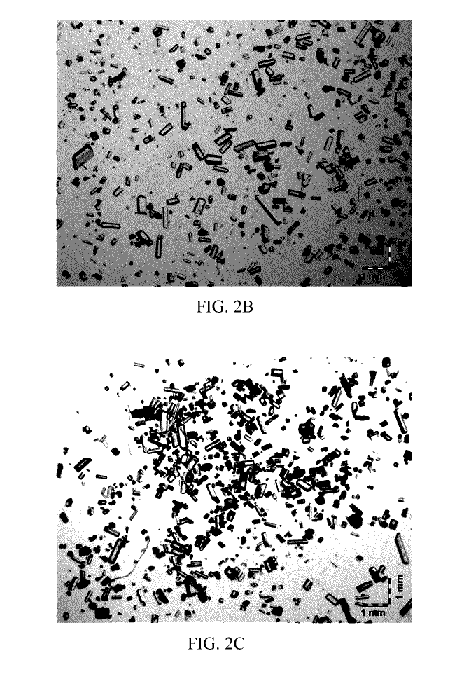

In Steps 5), 7), and 15), crystals were observed under a stereomicroscope (FIG. 2A to FIG. 2C), and crystal sponges were confirmed.

### Example 10

### Production Method of Crystal Sponges Using Sodium bis(trimethylsilyl)amide (NaHMDS)

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol) of zinc iodide and 132 μl (1.9 mol/l in THF, 0.25 mmol) of NaHMDS in MeOH (25 ml) was added thereto.

In Steps 5), 7), and 15), crystals were observed under a stereomicroscope, and crystal sponges were confirmed.

Based on the results of Example 10, in which the organometal NaHMDS was used as the additive for changing the solution properties to basic, it can be seen that the production method according to one embodiment of the invention can be implemented even by using an organometal as the additive for changing the solution properties to basic.

### Example 11

### Production Method of Crystal Sponges Using 1,1,3,3-Tetramethylguanidine (TMG)

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol) of zinc iodide and 31 μl of 1,1,3,3-tetramethylguanidine in MeOH (25 ml) was added thereto.

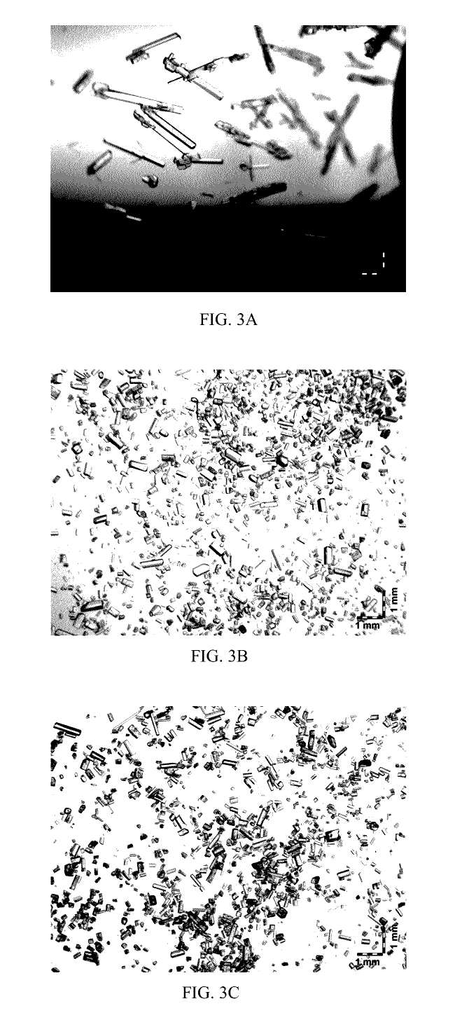

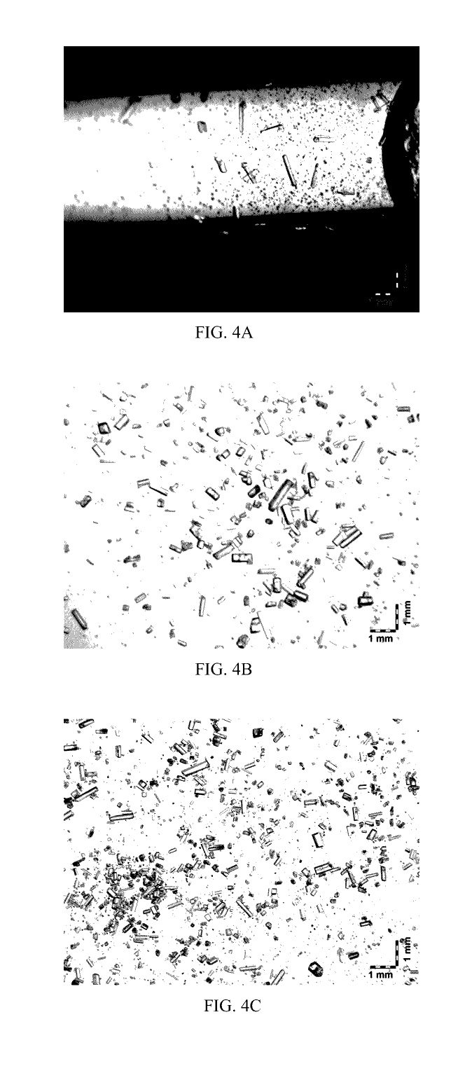

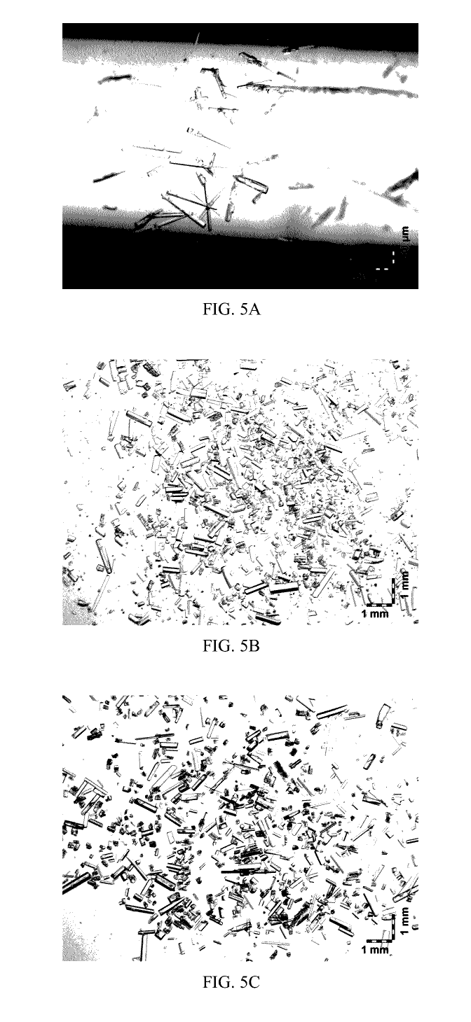

In Steps 5), 7), and 15), crystals were observed under a stereomicroscope, and crystal sponges were confirmed (FIG. 3A to FIG. 3C).

### Example 12

### Production Method of Crystal Sponges Using N,N′-Diisopropylethylamine (DIPEA)

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol) of zinc iodide and 44 μl of N,N′-diisopropylethylamine in MeOH (25 ml) was added thereto.

In Steps 5), 7), and 15), crystals were observed under a stereomicroscope, and crystal sponges were confirmed. (FIG. 4A to FIG. 4C).

### Example 13

### Production Method of Crystal Sponges Using Bis(isopropyl)amine

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol) of zinc iodide and 35 μl of bis(isopropyl)amine in MeOH (25 ml) was added thereto.

In Steps 5), 7), and 15), crystals were observed under a stereomicroscope, and crystal sponges were confirmed. (FIG. 5A to FIG. 5C).

### Example 14

### Production Method of Crystal Sponges Using n-Butylamine

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 319 mg (1.00 mmol, Kojundo Chemical Laboratory) of zinc iodide and n-butylamine 25 μl (0.25 mmol) in MeOH (25 ml) was added thereto.

In Steps 5), 7), and 15), crystals were observed under a stereomicroscope, and crystal sponges were confirmed.

Based on the results of Examples 9 to 14, in which an organic base (1,8-diazabicyclo[5.4.0]undec-7-ene, 1,1,3,3-tetramethylguanidine, N,N′-diisopropylethylamine, bis(isopropyl)amine or n-butylamine) was used as the additive for changing the solution properties to basic, it can be seen that the production method according to one embodiment of the invention can be implemented even by using an organic base as the additive for changing the solution properties to basic.

### Example 15

### Production Method of Crystal Sponges Using ZnBr₂ and Potassium Hydroxide

Based on the same method as in Example 1, in Steps 1) to 4), 5 ml of a solution obtained by dissolving 156 mg (0.50 mmol) of TPT (2,4,6-tri(pyridin-4-yl)-1,3,5-triazine) in a nitrobenzene (100 ml)/MeOH (25 ml) mixture was dispensed into each test tube, and 1 ml of a solution obtained by dissolving 563 mg (2.50 mmol, Kojundo Chemical Laboratory) of zinc bromide and 5 ml (0.5 mol in MeOH, 0.50 mmol, Kanto Kagaku) of KOH in MeOH (20 ml) was added thereto.

In Steps 5), 7), and 15), crystals were observed under a stereomicroscope, and crystal sponges were confirmed.

### Comparative Example 1

Based on the method described in Inokuma Y et al., Nature Protocols, Vol. 9 No. 2, (2014), pp. 246-252, crystal sponges were synthesized on half the scale (24 test tubes, half the used reagent amount). More specifically, in the test tubes, a solution of ZnI₂ in methanol was charged and diffused into a layer of 2,4,6-tri (4-pyridyl)-1,3,5-triazine (TPT) in nitrobezene/methanol to form single crystals of crystal sponges precipitating on the interfacial boundary between the two kinds of solution. The used reagents, amounts, reaction times, and the like were in accordance with the above publication. The resultant crystal sponges were recovered after they had fallen to the bottom of the test tubes by using an ultrasonic bath in the same manner as Example 1, and were ultimately stored in hexane. The TPT was purchased from Wako Pure Chemicals or TCI.

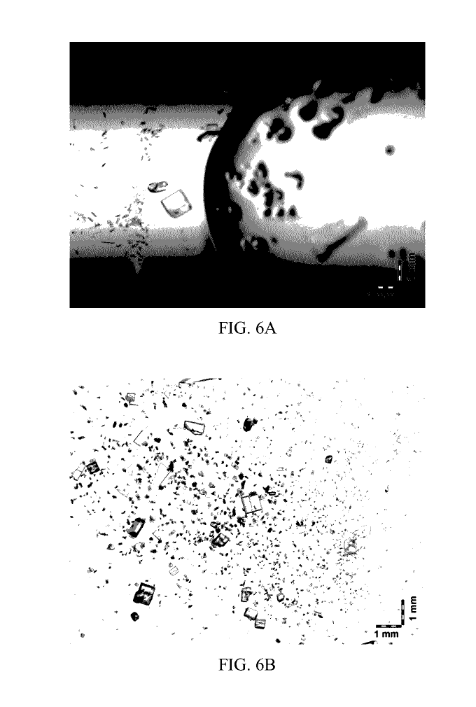

The appearance of the crystals when formed on the test tube walls and in the stored state was observed using a stereomicroscope (FIG. 6A and FIG. 6B).

Further, based on the same method as in Example 1, the number of crystal sponges contained in three test tubes randomly selected from among the 24 test tubes in which crystallization had been carried out was counted. The obtained average value was 5.7 (two in the first test tube, four in the second test tube, and 11 in the third test tube) (FIG. 6A and FIG. 6B). In this method, hardly any crystal sponges were formed.

### Comparative Example 2

### (Reference Example) Crystal Sponge Formation Reaction Using Hydrochloric Acid

Based on the same method as in Example 1, 24 test tubes were prepared, TPT 156 mg (0.50 mmol) of TPT (2,4,6-tri(pyridin-4-yl)-1,3,5-triazine) was dissolved in nitrobenzene (100 ml)/MeOH (25 ml), 0.125 ml (0.25 mmol) of a 2.0 M HCl-methanol solution (Kokusan Kagaku) was added, 5 ml of the resultant solution was dispensed into the test tubes, and 1 ml of a solution obtained by dissolving 247 mg (0.78 mmol) of zinc iodide in MeOH (25 ml) was further dispensed into each test tube.

In this method as well, hardly any crystal sponges were formed.

### Example 16

### Test Example 1

X-ray crystallography of guaiazulene was carried out using the crystal sponges synthesized in Example 1.

Based on the same method described in Inokuma Y et al., Nature Protocols, Vol. 9 No. 2, (2014), pp. 246-252, one crystal sponge having a suitable size was selected from among the crystal sponges formed in Example 1. After transferring to a cyclohexane solution, the hexane in the crystal sponge was replaced with cyclohexane, and the crystal sponge was transferred to an air-tight screw-top microvial together with about 45 μl of cyclohexane solution. Using a microsyringe, 10 μl of aqueous (1 μg/μl) of guaiazulene in cyclohexane was added to the microvial containing the crystal sponge. The screw cap of the microvial was screwed shut, and the microvial was left to stand for two days in an incubator set to 50° C.

As a result of incorporation of the guaiazulene, the crystals had turned dark blue. From X-ray crystallography of the resultant guaiazulene-including crystal sponge, a guaiazulene structure could be confirmed.

### INDUSTRIAL APPLICABILITY

According to one embodiment of the invention, a more efficient method is provided as a novel method for producing a polymer-metal complex. The polymer-metal complex may be used in crystal structure analysis of the active ingredients and the like of a pharmaceutical. Therefore, the present invention is expected to greatly contribute to the development of the pharmaceutical industry and related industries.

1. A method for producing a single crystal of a polymer-metal complex comprising a tridentate ligand and a metal ion that serves as a center metal, the polymer-metal complex having a three-dimensional network structure in which the ligand is coordinated to the metal ion, and having pores and voids that are three-dimensionally arranged in the three-dimensional network structure in an ordered manner, the method comprising:
(a) a step of dissolving in an organic solvent a tridentate ligand represented by formula (1): 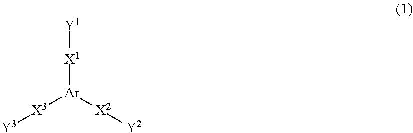
(wherein,
Ar represents an optionally substituted trivalent aromatic group,
X¹ to X³ each independently represent a divalent organic group, or a single bond that directly bonds Ar and Y¹, Y², or Y³, and
Y¹ to Y³ each independently represent a monovalent organic group having a coordinating moiety); and
(b) a step of obtaining the single crystal of the polymer-metal complex by adding to the solution obtained in step (a) a compound for providing the metal ion and an additive for changing solution properties to basic.

2. The method for producing a single crystal of a polymer-metal complex according to claim 1, wherein the additive for changing solution properties to basic is a base selected from a hydroxide of an alkali metal, a hydroxide of an alkaline earth metal, an organic base, and an organometallic compound.

3. The method for producing a single crystal of a polymer-metal complex according to claim 1, wherein the additive for changing solution properties to basic is lithium hydroxide, sodium hydroxide, potassium hydroxide, rubidium hydroxide, strontium hydroxide, 1,8-diazabicyclo[5.4.0]undec-7-ene, sodium bis(trimethylsilyl)amide, 1,1,3,3-tetramethylguanidine, or N,N-diisopropylethylamine.

4. The method for producing a single crystal of a polymer-metal complex according to claim 1, wherein the metal ion that serves as a center metal is a cobalt ion or a zinc ion.

5. The method for producing a single crystal of a polymer-metal complex according to claim 1, wherein the polymer-metal complex is represented by formula:
[(M(Z)₂)₃(L)₂]ₙ
(wherein,
M represents a metal ion,
Z represents a monovalent anion,
n represents an arbitrary natural number, and
L is a compound represented by formula (1)).

6. A method for preparing a crystal structure analysis sample in which a molecule of an organic compound for which a molecular structure is to be determined is arranged in pores and voids of a polymer-metal complex crystal in an ordered manner, the method comprising:
(c) a step of bringing a single crystal of a polymer-metal complex crystal obtained by the production method according to claim 1 into contact with a first organic solvent; and
(d) a step of immersing the single crystal of the polymer-metal complex of step (c) in a second organic solvent comprising the organic compound for which a molecular structure is to be determined, and then concentrating by volatilizing the organic solvent under mild conditions.

7. The method for preparing a crystal structure analysis sample according to claim 6, wherein the first organic solvent is an alkane solvent or a cycloalkane solvent.

8. A kit for preparing a crystal structure analysis sample in which a molecule of an organic compound for which a molecular structure is to be determined is arranged in pores and voids of a polymer-metal complex crystal in an ordered manner, the kit comprising:
(i) a tridentate ligand represented by formula (1): 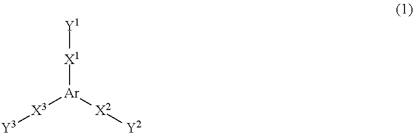
(wherein,
Ar represents an optionally substituted trivalent aromatic group,
X¹ to X³ each independently represent a divalent organic group, or a single bond that directly bonds Ar and Y¹, Y², or Y³, and
Y¹ to Y³ each independently represent a monovalent organic group having a coordinating moiety);
(ii) a compound for providing the metal ion that serves as a center metal of the polymer-metal complex; and
(iii) an additive for changing solution properties to basic.
